(19) United States
(12) Patent Application Publication
(10) Pub. No.: US 2005/0090067 A1
(43) Pub. Date: Apr. 28, 2005

(54) Silicide formation for a semiconductor device

(76) Inventor: Dharmesh Jawarani, Round Rock, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/694,077

(22) Filed: Oct. 27, 2003

(51) Int. Cl. H01L 21/336; H01L 21/425; H01L 21/3205

(52) U.S. Cl. 438/305; 438/301; 438/592; 438/528; 438/532; 438/655

(57) ABSTRACT

A polysilicon line (22), used e.g. as a gate, has a portion (30) amorphized by implanting (19) particles having a relatively large atomic mass. The amorphized portion is used to form a metal silicide (38) having a desirably low sheet resistance. Exemplary metals are cobalt and nickel that can provide the thin lines of below 50 nanometers. An exemplary particle for implanting that has sufficient atomic mass is xenon. The dose and the energy of the implant (19) are potentially different based on the linewidth (21) of the polysilicon line (22).

### BACKGROUND OF THE INVENTION

1. Field of the Invention

This invention relates in general to semiconductor processing and more specifically to the formation of silicides.

2. Description of the Related Art

Semiconductor device fabrication may involve forming silicides on the source/drain regions and a gate of a semiconductor device. However, a metal silicide formed on a gate may exhibit an undesirably high sheet resistance, especially for a device with a small linewidth.

For cobalt silicides, an undesirably high sheet resistance may be related to the unavailability of a sufficient number of nuclei on which the low resistivity CoSi₂ phase nucleates. This may lead to a non-uniform, discontinuous CoSi₂ film with several voids, leading to unacceptable sheet resistance for the silicide layer on the gate.

What is needed is an improved gate silicide.

### BRIEF DESCRIPTION OF THE DRAWINGS

The present invention may be better understood, and its numerous objects, features, and advantages made apparent to those skilled in the art by referencing the accompanying drawings.

FIG. 1 is a partial side cut away view of one embodiment of a wafer during a stage in the manufacture of a semiconductor device according to the present invention.

FIG. 2 is a partial side cut away view of one embodiment of a wafer during another stage in the manufacture of a semiconductor device according to the present invention.

FIG. 3 is a partial side cut away view of one embodiment of a wafer during another stage in the manufacture of a semiconductor device according to the present invention.

FIG. 4 is a partial side cut away view of one embodiment of a wafer during another stage in the manufacture of a semiconductor device according to the present invention.

The use of the same reference symbols in different drawings indicates identical items unless otherwise noted.

### DETAILED DESCRIPTION

The following sets forth a detailed description of a mode for carrying out the invention. The description is intended to be illustrative of the invention and should not be taken to be limiting.

It has been discovered that implanting a gate with xenon ions prior to the formation of the gate silicide may reduce the sheet resistance of the gate silicide, thereby improving device characteristics and yield.

FIG. 1 is a partial cut away side view of a semiconductor wafer according to the present invention. Wafer 10 includes a semiconductor substrate 12 with a gate 22 formed there over. Source/drain regions 14 and 16 are located in substrate 12. In one embodiment, source/drain regions 14 and 16 have been formed by the ion implantation of a dopant (not shown) in those areas. In the embodiment shown, regions 14 and 16 are formed with two ion implants and a subsequent anneal with the first ion implant for implanting dopant for the source/drain extensions and a second ion implant for implanting dopant for the deep source/drain region portions. A gate oxide 20 is located between gate 22 and substrate 12. A dielectric liner 18 is located over substrate 12 and gate 22. In one embodiment, liner 18 is a layer of silicon dioxide having a thickness of 150 Å and is formed prior to the implantation of dopant to form the deep source/drain region portions of source/drain regions 14 and 16. In other embodiments, liner 18 may have other thicknesses and/or be made of other materials. A sidewall spacer 24 is located adjacent to gate 22 and is formed after liner 18.

In the embodiment shown, gate 22 is a polysilicon line having a linewidth 21 as designated in FIG. 1. In one embodiment, the linewidth is 30 nanometers but may be of other sizes (e.g. 40 nm, 20 nm, or 15 nm) in other embodiments.

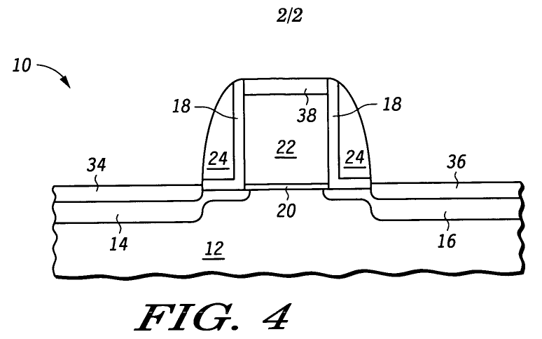

As shown in FIG. 1, xenon ions (as represented by arrows 19) are implanted into wafer 10 including into gate 22 and source/drain regions 14 and 16 through liner 18. These xenon ions are being implanted to amorphize the top portions of the gate 22 and source/drain regions 14 and 16 so as to reduce the sheet resistance of metal silicides (see silicides 38, 34, and 36 of FIG. 4) formed on those structures at a later stage.

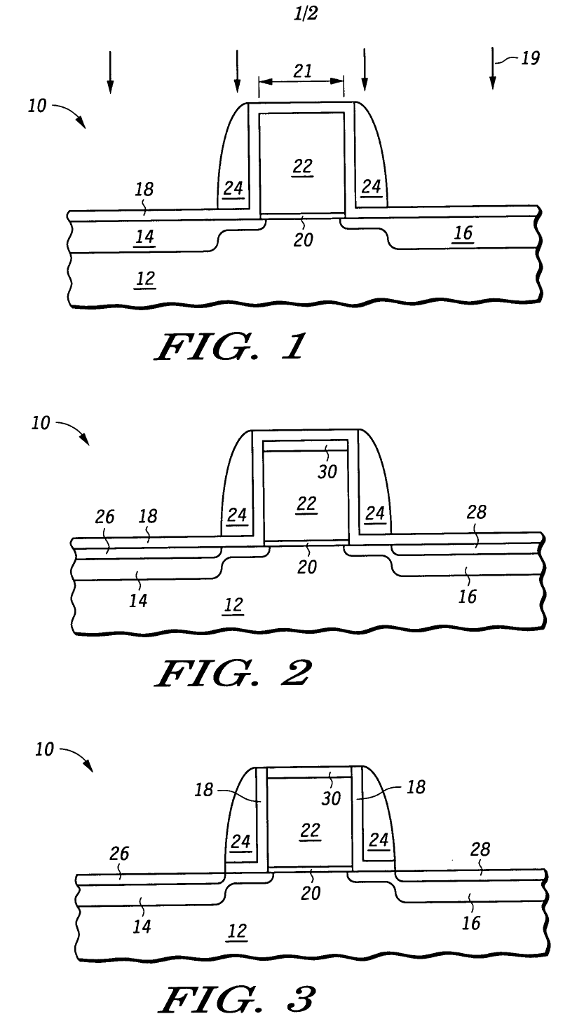

FIG. 2 shows a partial cut away side view of wafer 10 after the implantation of xenon ions into the top portions of gate 22, source/drain region 14 and source/drain region 16 to form amorphized region 30 in gate 22, amorphized region 26 in source/drain region 14, and amorphized region 28 in source/drain region 16. In one embodiment, amorphized regions 26, 28, and 30 have a thickness of 30 nm, but may have other thicknesses in other embodiments.

In one embodiment, it is preferable that the xenon ions are implanted at energies and doses sufficient to amorphize the top portions of gate 22 such that the amorphize gate region 30 extends only into the portion of gate silicon consumed in subsequent silicide steps. However, in other embodiments, the ions may be implanted at energies (and doses) that are greater than or less than such levels. In some embodiments, extending the amorphized gate region deeper into the gate may cause the xenon to penetrate through the gate oxide 20 which may lead to undesirable leakage in a transistor formed from the gate and source/drain regions due to damage to the lattices of those regions. In some embodiments, too shallow of an amorphized region may lead to less than desired silicide thicknesses.

In some embodiments where the linewidths are 50 nanometers or less, the xenon ions are implanted at energies of 30 KeV or less and at doses of 2e14 atoms per cm squared or less. In one embodiment having a linewidth of 40 nanometers, the xenon ions are implanted at an energy of 20 KeV and at a dosage of 1e14 atoms per cm squared. In other embodiments having linewidths ranging from 30-50 nanometers, the xenon ions are implanted at an energy ranging between 15-30 KeV and at a dosage ranging from 1e13-2e14 atoms per cm squared. In one embodiment, where the linewidth is between 20-30 nanometers, the xenon ions are implanted at an energy 15 KeV and at a dosage of 6e13 atoms per cm squared. In other embodiments having a linewidth that ranges from 20-30 nanometers, the xenon ions are implanted at an energy ranging between 10-25 KeV and at a dosage ranging from 1e13-1e14 atoms per cm squared.

For some embodiments with linewidths less than 20 nanometers (e.g. 15 nm or 10 nm), the xenon ions are implanted at energies and doses equal to or less than those given above for 20-30 nanometer linewidths. In other embodiments, xenon ions may be implanted at other energies and doses depending upon process conditions.

It is believed that the relatively high atomic mass of xenon (a.m.u. 132) restricts an amorphized region formed from the implantation of xenon to a more sharply defined region, thereby minimizing the damage to silicon locations adjacent and beneath the amorphized region. A more sharply defined amorphized region may lead to a better quality silicide that is formed from that region. Accordingly, the use of xenon ions to amorphize portions of the gate and source/drain regions may provide for a reduction in sheet resistances of the gate silicide and source/drain silicides while minimizing the damage to the gate lattice and source/drain region lattices. Also, the use of xenon to amorphize such regions may provide a more uniform silicide layer on the source/drain regions thereby reducing junction leakage. Also, the use of xenon to amorphize such regions may also tighten distribution of electrical parameters such as miller capacitance, drive currents, and leakage currents as well as reduce the metal to silicide contact resistance. Accordingly, in some embodiments, amorphized regions formed by the implantation of xenon ions at the energies and doses given above may produce these advantages in silicides formed there from. Particles having a lower atomic mass have been utilized to form amorphized regions but the regions formed are not as sharply defined which may cause defects that result e.g. in increased leakage.

FIG. 3 is a partial side cut away side view of wafer 10 after the removal of portions of liner 18 over gate 22 and source/drain regions 14 and 16. In some embodiments, xenon ion implantation may be performed after the removal of these portions of liner 18.

FIG. 4 is a partial side cut away view of wafer 10 after the formation of a gate silicide 38 on gate 22, a source/drain silicide 34 on source/drain region 14, and a source/drain silicide 36 on source/drain region 16. In one embodiment, silicides 34, 38, and 36 are cobalt silicides. In other embodiments, these silicides may include other metals such as e.g. nickel.

In one embodiment, silicides 34, 38, and 36 are formed by the deposition of a metal (e.g. including cobalt or nickel) (not shown) over wafer 10 (as in its condition as shown in FIG. 3). The wafer is heated for the metal to react with the exposed silicon to form a metal silicide. Amorphized silicon (e.g. regions 26, 28, and 30) may be partially or fully consumed during the reaction. Afterwards, the unreacted metal is stripped away with a metal selective etch. In some embodiments, a second anneal may be performed to form the low resistivity silicide phase. In one embodiment, the silicides have a thickness of approximately 30 nm, but may have other thicknesses in other embodiments.

In subsequent processing steps, contacts may be formed that electrically contact the silicides (e.g. 34, 38, and 36).

In other embodiments, xenon ions may be implanted to amorphize a portion of other types of polysilicon lines for the formation of silicides on those structures. Examples of other such types of polysilicon lines include e.g. silicided resistors and polysilicon snakes located over the field regions.

In other embodiments, other types of “heavy” ions may be used to amorphize a silicon region for silicide formation. For example, lead (a.m.u. 207) or radon (a.m.u. 222) ions may be used to amorphize such regions.

In one embodiment, a method of making a semiconductor device includes providing a semiconductor substrate and forming a gate over the substrate. The gate comprises a polysilicon line of a linewidth less than or equal to 50 nanometers. The polysilicon line has a dielectric liner layer there over. The method also includes forming a first source/drain region adjacent to the gate on a first side of the gate and a second source/drain region adjacent the gate on a second side of the gate. The dielectric liner layer extends over the first source/drain region and the second source/drain region. The method also includes implanting xenon into the polysilicon line at an energy and a dosage to amorphize an upper portion of the polysilicon line. If the linewidth is between 20 and 30 nanometers, then the dosage is between 1E13 and 1E14 particles per centimeter squared and the energy is between 10 KeV and 25 KeV. If the linewidth is between 30 nanometers and 50 nanometers, then the dosage is between 1E13 and 2E14 particles per centimeter squared and the energy is between 15 KeV and 30 KeV. If the linewidth is less than 20 nanometers, then the dosage is less than or equal to 1E14 particles per centimeter squared and the energy is less than or equal to 25 KeV. The method also includes forming a metal silicide with the amorphized upper portion of the polysilicon line. The metal silicide includes one of cobalt and nickel.

In another embodiment, a method for forming a semiconductor device includes providing a polysilicon line over a semiconductor substrate. The polysilicon line is characterized as having a linewidth of less than or equal to 50 nanometers. The method also includes implanting xenon into the polysilicon line to amorphize an upper portion of the polysilicon line. The implanting is at a dosage of less than or equal to 2E14 particles per centimeter squared and an energy of less than or equal to 30 KeV. The method further includes forming a metal silicide with the amorphized upper portion of the polysilicon line.

In another embodiment, a method of forming a semiconductor device includes forming a polysilicon line having a linewidth of less than or equal to 50 nanometers over a semiconductor substrate and implanting particles having an atomic mass at least equal to that of xenon into the polysilicon line to amorphize an upper portion of the polysilicon line. The implanting is at an energy of less than or equal to 30 KeV and a dosage of less than or equal to 2E14 particles per centimeter squared. The method further includes forming a metal silicide with the amorphized upper portion of the polysilicon line.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. A method of making a semiconductor device, comprising:
providing a semiconductor substrate;
forming a gate over the substrate, wherein the gate comprises a polysilicon line of a linewidth less than or equal to 50 nanometers, wherein the polysilicon line has a dielectric liner layer there over;
forming a first source/drain region adjacent to the gate on a first side of the gate and a second source/drain region adjacent the gate on a second side of the gate, wherein the dielectric liner layer extends over the first source/drain region and the second source/drain region;
implanting xenon through the dielectric liner layer into the polysilicon line at an energy and a dosage to amorphize an upper portion of the polysilicon line, wherein:
if the linewidth is between 20 and 30 nanometers, then the dosage is between 1E13 and 1E14 particles per centimeter squared and the energy is between 10 KeV and 25 KeV;
if the linewidth is between 30 nanometers and 50 nanometers, then the dosage is between 1E13 and 2E14 particles per centimeter squared and the energy is between 15 KeV and 30 KeV; and
if the linewidth is less than 20 nanometers, then the dosage is less than or equal to 1E14 particles per centimeter squared and the energy is less than or equal to 25 KeV; and
forming a metal silicide with the amorphized upper portion of the polysilicon line, wherein the metal silicide includes one of cobalt and nickel.

2. The method of claim 1, further comprising forming a sidewall spacer around the gate.

3. The method of claim 1, wherein the metal silicide is cobalt silicide.

4. The method of claim 1, wherein the first source/drain region and the second source/drain region are formed in the substrate.

5. The method of claim 1, wherein the dielectric liner layer comprises oxide.

6. The method or claim 1, wherein the implanting causes amorphization of upper portions of the first source/drain region and the second source/drain region, wherein the method further comprises forming metal silicides with the amorphized upper portions of the first source/drain region and the second source/drain region.

7. A method for forming a semiconductor device, comprising:
providing a polysilicon line over a semiconductor substrate, the polysilicon line characterized as having a linewidth of less than or equal to 50 nanometers;
providing a dielectric liner over the polysilicon line;
implanting xenon through the dielectric liner into the polysilicon line to amorphize an upper portion of the polysilicon line, where the implanting is at a dosage of less than or equal to 2E14 particles per centimeter squared and an energy of less than or equal to 30 KeV; and
forming a metal silicide with the amorphized upper portion of the polysilicon line.

8. The method of claim 7, wherein the metal silicide includes cobalt.

9. The method of claim 7, wherein the metal silicide includes nickel.

10. The method of claim 7, wherein the linewidth is less than or equal to about 30 nanometers, the dosage is less than or equal to 1E14 particles per centimeter squared, and the energy is less than or equal to 25 KeV.

11. The method of claim 10, wherein the linewidth is about 30 nanometers, the energy is about 15 KeV, and the dosage is about 6E13 particles per centimeter squared.

12. The method of claim 7, wherein the linewidth is about 40 nanometers, the energy is about 20 KeV, and the dosage is about 1E14 particles per centimeter squared.

13. The method of claim 7, further comprising forming a first source/drain region on a first side of the polysilicon line and a second source/drain region on a second side of the polysilicon line prior to the implanting.

14. The method of claim 13, wherein the implanting causes amorphization of upper portions of the first source/drain region and the second source/drain region.

15. The method of claim 14, wherein a metal silicide is formed with the amorphized upper portions of the first source/drain region and the second source/drain region.

16. (Canceled)

17. The method of claim 7, wherein the dosage is greater than 1E13 particles per centimeter squared.

18. The method of claim 7, wherein the energy is greater than 10 KeV.

19. The method of claim 7, wherein if the linewidth is between 20 and 30 nanometers, then the dosage is between 1E13 and 1E14 particles per centimeter squared and the energy is between 10 KeV and 25 KeV.

20. The method of claim 7, wherein if the linewidth is between 30 nanometers and 50 nanometers, then the dosage is between 1E13 and 2E14 particles per centimeter squared and the energy is between 15 KeV and 30 KeV.

21. The method of claim 7, wherein if the linewidth is less than 20 nanometers, then the dosage is less than or equal to 1E14 particles per centimeter squared and the energy is less than or equal to 25 KeV.

22. A method of forming a semiconductor device, comprising:
forming a polysilicon line having a linewidth of less than or equal to 50 nanometers over a semiconductor substrate;
forming a liner over the polysilicon line;
implanting particles having an atomic mass at least equal to that of xenon through the liner into the polysilicon line to amorphize an upper portion of the polysilicon line, wherein the implanting is at an energy of less than or equal to 30 KeV and a dosage of less than or equal to 2E14 particles per centimeter squared; and
forming a metal silicide with the amorphized upper portion of the polysilicon line.

23. The method of claim 22, wherein the metal silicide comprises cobalt silicide.

24. The method of claim 22, wherein the linewidth is less than about 30 nanometers, the dosage is less than or equal to 1E14 particles per centimeter squared, and the energy is less than or equal to 20 KeV.

25. The method of claim 22, wherein the particles includes xenon.

26. The method of claim 22, further comprising forming source/drain regions adjacent to the line prior to the implanting, wherein the implanting is further characterized as amorphizing upper portions of the source/drain regions and wherein metal silicide is formed with the amorphized upper portions of the source/drain regions.

27. The method of claim 26, wherein the forming the liner over the polysilicon line further includes forming the liner over the source/drain regions prior to implanting and removing portions of the liner prior to forming the metal silicide.

28. The method of claim 22, wherein if the linewidth is between 20 and 30 nanometers, then the dosage is between 1E13 and 1E14 particles per centimeter squared and the energy is between 10 KeV and 25 KeV.

29. The method of claim 22, wherein if the linewidth is between 30 nanometers and 50 nanometers, then the dosage is between 1E13 and 2E14 particles per centimeter squared and the energy is between 15 KeV and 30 KeV.

30. The method of claim 22, wherein if the linewidth is less than 20 nanometers, then the dosage is less than or equal to 1E14 particles per centimeter squared and the energy is less than or equal to 25 KeV.

31. A method of forming a semiconductor device, comprising:
forming a polysilicon line over a semiconductor substrate;
forming a liner over the polysilicon line;
implanting particles having an atomic mass at least equal to that of xenon through the liner into the polysilicon line to amorphize an upper portion of the polysilicon line; and
forming a metal silicide with the amorphized upper portion of the polysilicon line.
